(19) United States
(12) Patent Application Publication
(10) Pub. No.: US 2025/0249491 A1
(43) Pub. Date: Aug. 7, 2025

(54) CHEMICAL SUPPLY APPARATUS AND CHEMICAL EXCHANGE METHOD

(71) Applicant: SEMES CO., LTD., Cheonan-si (KR)

(72) Inventors: Yun Seok JEON, Cheonan-si (KR); Hyeon Suk PARK, Cheonan-si (KR); Seon Min KIM, Cheonan-si (KR)

(21) Appl. No.: 19/042,432

(22) Filed: Jan. 31, 2025

(30) Foreign Application Priority Data
Feb. 2, 2024 (KR) 10-2024-0016409

(51) Int. Cl. B08B 9/08; H01L 21/67

(52) U.S. Cl. CPC B08B 9/08; B08B 2209/08; H01L 21/67017

(57) ABSTRACT

The present disclosure provides a chemical supply apparatus of a liquid processing apparatus. The chemical supply apparatus of a liquid processing apparatus may include: a first tank and a second tank storing liquid to be supplied to the substrate processing apparatus; a liquid supply source supplying a chemical to the first tank and the second tank; a main circulation line connected to the first tank and the second tank and supplying liquid to the substrate processing apparatus; and a control unit controlling the tanks and the main circulation line to perform a flushing mode that drains the liquid accommodated in the first tank and the second tank, supplies a flushing liquid to the first tank, collects the flushing liquid to the second tank from the main circulation line, and then drains the flushing liquid.

### CROSS-REFERENCE TO RELATED APPLICATIONS

This application claims priority to and the benefit of Korean Patent Application No. 10-2024-0016409 filed in the Korean Intellectual Property Office on Feb. 2, 2024, the entire contents of which are incorporated herein by reference.

### TECHNICAL FIELD

The present disclosure relates to a chemical supply apparatus and a chemical exchange method.

### BACKGROUND ART

Contaminants such as particles, organic contaminants, or metallic contaminants remaining on a substrate surface significantly affect the characteristics and production yields of semiconductor devices. For this reason, a cleaning process of removing various contaminants attached to a substrate surface is very important in a semiconductor manufacturing process, and a process of cleaning a substrate is performed before and after each unit process for manufacturing a semiconductor. As a process for removing such contaminants, there is a cleaning process using deionized water or chemical.

In the substance cleaning process, when chemical reaches its lifetime, chemical exchange that discharges all the chemical remaining in a tank and exchanges the chemical with a new chemical is performed. A flushing process for removing remaining chemical in a supply line connected to the tank is required before the chemical exchange. The flushing process is a process of filling an emptied tank with deionized water, diluting the chemical by circulating the deionized water though a supply line, and then draining it, and this flushing process is repeatedly performed several times. In particular, there is no standard for the amount of use of deionized water and the flushing time based on the type of chemical, the temperature of chemical, or the mixing ratio of chemical, so they are determined at the discretion of workers.

### SUMMARY OF THE INVENTION

An objective of the present disclosure is to provide a chemical supply apparatus and a chemical exchange method that can quickly remove remaining chemical in a supply line in a chemical exchange process of exchanging chemical, which reached its lifetime, with new chemical.

Another objective of the present disclosure is to provide a chemical supply apparatus and a chemical exchange method that can quantify a flushing fluid during a flushing process of a supply line.

Another objective of the present disclosure is to provide a chemical supply apparatus and a chemical exchange method that can optimize the amount of water and flushing time of a flushing fluid that is used to flush a supply line, depending on the type of chemical, the concentration of the chemical, or the mixing ratio of the chemical.

The objectives of the present disclosure are not limited thereto and other objectives not stated herein may be clearly understood by those skilled in the art from the following description.

An exemplary embodiment of the present invention, a chemical supply apparatus that supplies a chemical to a substrate processing apparatus, the chemical supply apparatus comprising: a first tank and a second tank storing liquid to be supplied to the substrate processing apparatus; a liquid supply source supplying a chemical to the first tank and the second tank; a main circulation line connected to the first tank and the second tank and supplying liquid to the substrate processing apparatus; and a control unit controlling the tanks and the main circulation line to perform a flushing mode that drains the liquid accommodated in the first tank and the second tank, supplies a flushing liquid to the first tank, collects the flushing liquid to the second tank from the main circulation line, and then drains the flushing liquid.

According to an embodiment of the present disclosure, the chemical supply apparatus may further include a first sub-circulation line circulating the liquid stored in the first tank; and a second sub-circulation line circulating the liquid stored in the second tank, wherein the flushing liquid collected to the second tank may drained through a drain line connected to the second sub-circulation line.

According to an embodiment of the present disclosure, the first sub-circulation line and the second sub-circulation may include a common line equipped with a pump to share one pump.

According to an embodiment of the present disclosure, the drain line may diverges from the common line.

According to an embodiment of the present disclosure, the control unit performs control such that a flushing liquid is supplied to the first tank while the flushing mode may performed.

According to an embodiment of the present disclosure, the control unit finishes the flushing mode when a flow rate of a flushing liquid that may provide to the second tank through the main circulation line reaches a target flow rate.

According to an embodiment of the present disclosure, the control unit drains the flushing liquid in the first tank and the second tank when the flushing mode may finished.

According to an embodiment of the present disclosure, the control unit may controls the tanks and the main circulation line: to perform a flushing mode that supplies a flushing liquid to the first tank, collects the flushing liquid to the second tank through the main circulation line, and then drains the flushing liquid; and then to perform an additional flushing mode that supplies a flushing liquid to the second tank, collects the flushing liquid to the first tank through the main circulation line, and then drains the flushing liquid.

According to an embodiment of the present disclosure, the flushing liquid collected to the first tank may drained through a drain line connected to the common line.

According to an embodiment of the present disclosure, the flushing liquid may deionized water.

An exemplary embodiment of the present invention, a chemical exchange method in a chemical processing apparatus including a first tank, a second tank, and a main circulation line connected to the first tank and the second tank, the chemical exchange method comprising: a flushing step of draining a chemical accommodated in the first tank and the second tank, supplying a flushing liquid to the first tank, collecting the flushing liquid to the second tank through the main circulation line, and then draining the flushing liquid; and a chemical exchange step of exchanging chemicals by supplying a new chemical to the first tank and the second tank.

According to an embodiment of the present disclosure, the flushing liquid collected to the second tank may drained through a drain line connected to a sub-circulation line circulating the chemical stored in the second tank.

According to an embodiment of the present disclosure, a flushing liquid may supplied to the first tank while the flushing step is performed.

According to an embodiment of the present disclosure, the flushing mode may finished when a flow rate of a flushing liquid that is provided to the second tank through the main circulation line reaches a target flow rate.

According to an embodiment of the present disclosure, the flushing step may include: a primary flushing mode that supplies a flushing liquid to the first tank, collects the flushing liquid to the second tank through the main circulation line, and then drains the flushing liquid; and a secondary flushing mode that supplies a flushing liquid to the second tank, collects the flushing liquid to the first tank through the main circulation line, and then drains the flushing liquid.

According to an embodiment of the present disclosure, the flushing liquid collected to the first tank in the secondary flushing mode may drained through a drain line connected to a sub-circulation line circulating the chemical stored in the first tank.

According to an embodiment of the present disclosure, the flushing liquid may deionized water.

An exemplary embodiment of the present invention, a chemical exchange method in a chemical supply apparatus including a first tank, a second tank, and a main circulation line connected to the first tank and the second tank, the chemical exchange method comprising: draining a chemical accommodated in the first tank and the second tank; a flushing step of supplying a flushing liquid to the first tank, collecting the flushing liquid to the second tank through the main circulation line, and then draining the flushing liquid, and of supplying a flushing liquid to the second tank, collecting the flushing liquid to the first tank through the main circulation line, and then draining the flushing liquid; and a chemical exchange step of exchanging chemicals by supplying a new chemical to the first tank and the second tank, wherein the flushing step may finished when a flow rate of the flushing liquid passing through the main circulation line reaches a target flow rate.

According to an embodiment of the present disclosure, the flushing liquid collected to the second tank may drained through a drain line connected to a sub-circulation line circulating the chemical stored in the second tank.

According to an embodiment of the present disclosure, the flushing liquid collected to the first tank may drained through a drain line connected to a sub-circulation line circulating the chemical stored in the first tank.

According to an embodiment of the present disclosure, there is a distinct effect that it is possible to quickly remove the remaining chemical in circulation lines in a chemical exchange process of replacing a chemical reaching its lifetime with a new chemical.

According to an embodiment of the present disclosure, there is a distinct effect that it is possible to optimize the deionized water usage and the flushing time for flushing circulation lines regardless of the type of a chemical, the concentration of a chemical, and the mixing ratio of a chemical.

According to an embodiment of the present disclosure, there is a distinct effect that, by quantifying the accurate deionized water usage through a flow meter in a flushing mode, the accuracy of the flushing mode (pipeline neutralization) can be ensured, and thus, the flushing mode can be reported in a computerized report format, whereby it is possible to expect a distinct effect being able to lower the environmental safety grade.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a view showing a substrate processing apparatus according to an embodiment of the present disclosure.

FIG. 2 is a view schematically showing an embodiment of the liquid processing chamber of FIG. 1.

FIG. 3 is a view illustrating a chemical supply apparatus connected to the liquid processing chamber.

FIG. 4 is a flowchart illustrating a chemical supply method in the chemical supply apparatus.

FIG. 5 to FIG. 6 are views sequentially showing a flushing process in the chemical supply method.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

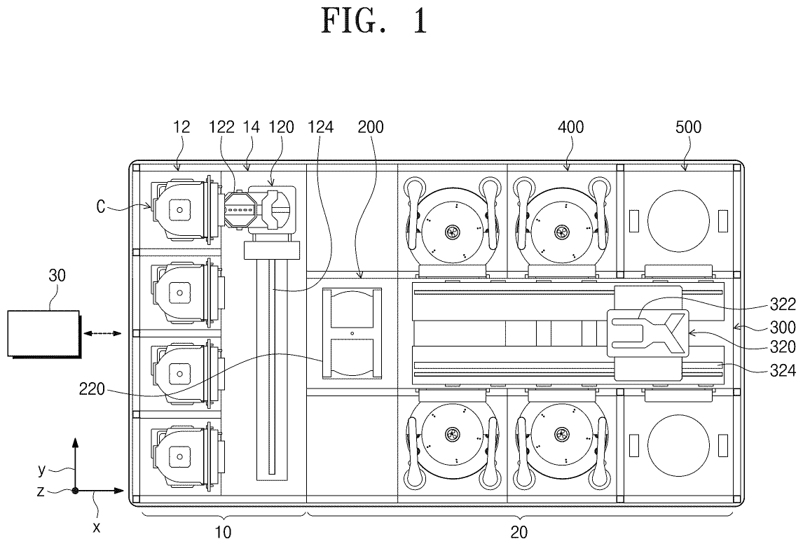

Hereafter, embodiments of the present disclosure are described with reference to FIG. 1 to FIG. 6.

FIG. 1 is a view showing a substrate processing apparatus according to an embodiment of the present disclosure.

Referring to FIG. 1, a substrate processing apparatus includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates W to the processing module 20 from containers C accommodating the substrates W and puts the substrates W processed at the processing module 20 into the containers C. The longitudinal direction of the index module 10 is provided in the second direction Y. The index module 10 has a load port 12 and an index frame 14. The load port 12 is positioned at the opposite side to the processing module 20 with the index frame 14 therebetween. The container C accommodating substrates W are placed in the load port 12. A plurality of load ports 12 may be provided and the plurality of load ports 12 may be disposed in the second direction Y.

The container C may be a container for sealing such as a Front Open Unified Pod (FOUP). The container C may be placed on the load port 12 by a worker or a conveying device (not shown) such as an overhead transfer, an overhead conveyor, or an automatic guided vehicle.

An index robot 120 is provided in the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates W are placed and the hand 122 may be provided to be able to move forward and backward, rotate about the third direction Z, and move in the third direction Z. A plurality of hands 122 may be provided to be spaced apart from each other in the up-down direction and the hands 122 can move forward and backward independently from each other.

The control unit 30 can control the substrate processing apparatus. The control unit 30 may include: a process controller that is a microprocessor (computer) that performs control of the substrate processing apparatus; a user interface that is a keyboard through which an operator performs command input operation, etc. to manage the substrate processing apparatus, a display that visualizes and displays the operation situation of the substrate processing apparatus, etc.; and a memory that stores a control program for performing processing, which is performed in the substrate processing apparatus, under control of the process controller, a program for performing processing on each component in accordance with various data and processing conditions, that is, a processing recipe. Further, the user interface and the memory may be connected to the process controller. The processing recipe may be stored in a memory medium of the memory and the memory medium may be a hard disk and may be a portable disc, such as a CD-ROM and a DVD, or a semiconductor memory such as a flash memory.

The processing module 20 includes a buffer unit 200, a transfer chamber 300, a liquid processing chamber 400, and a drying chamber 500. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying a liquid onto the substrates W. The drying chamber 500 can perform a drying process that removes a liquid remaining on substrates W. The transfer chamber 300 transfers substrates W between the buffer unit 200, the liquid processing chamber 400, and the drying chamber 500.

The longitudinal direction of the transfer chamber 300 may be provided in the first direction X. The buffer unit 200 may be disposed between the index module 10 and the transfer chamber 300. The liquid processing chamber 400 and the drying chamber 500 may be disposed on sides of the transfer chamber 300. The liquid processing chamber 400 and the transfer chamber 300 may be disposed in the second direction Y. The drying chamber 500 and the transfer chamber 300 may be disposed in the second direction Y. The buffer unit 200 may be positioned at an end of the transfer chamber 300.

According to an embodiment, the liquid processing chambers 400 may be disposed at both sides of the transfer chamber 300, the drying chambers 500 may be disposed at both sides of the transfer chamber 300, and the liquid processing chambers 400 may be disposed at positions close to the buffer unit 200 in comparison to the drying chambers 500. The liquid processing chambers 400 may be provided in an array of A×B (A and B are each a natural number of 1 or more) in the first direction X and the third direction Z, respectively, at a side of the transfer chamber 300. Further, the drying chambers 500 may be provided by the number of C×D (C and D are each a natural number of 1 or more) in the first direction X and the third direction Z, respectively, at a side of the transfer chamber 300. Unlike the above description, only the liquid processing chambers 400 may be provided at a side of the transfer chamber 300 and only the drying chambers 500 may be provided at another side.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates W are placed and the hand 322 may be provided to be able to move forward and backward, rotate about the third direction Z, and move in the third direction Z. A plurality of hands 322 may be provided to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through the front face and the transfer robot 320 can approach the buffer unit 200 through the rear face.

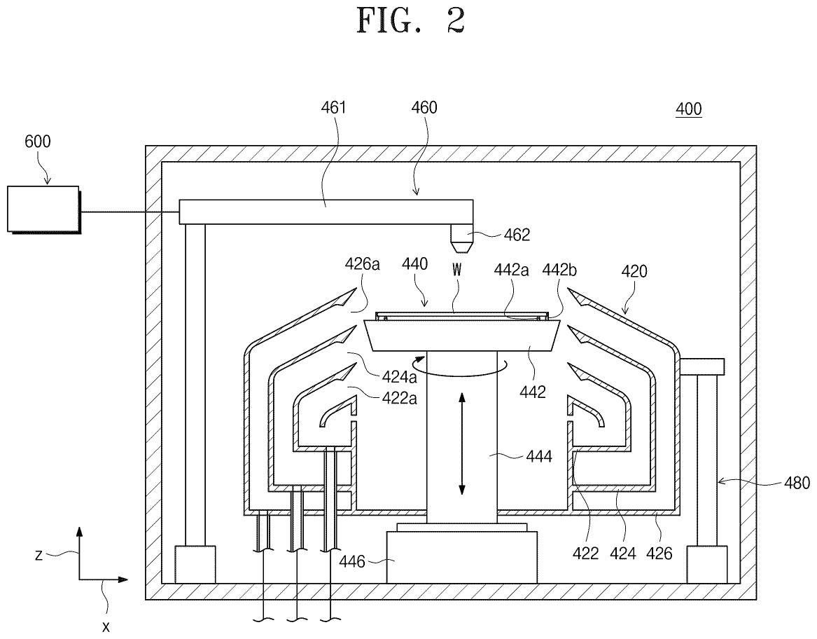

FIG. 2 is a view schematically showing an embodiment of the liquid processing chamber of FIG. 1.

Referring to FIG. 2, the liquid processing chamber 400 includes a housing 410, a cup 420, a supporting unit 440, and a liquid spray unit 460, and an elevation unit 480.

The housing 410 may have an internal space in which substrates W are processed. The housing 410 may have a substantially hexahedral shape. For example, the housing 410 may have a rectangular cuboid shape. Further, an opening (not shown) through which substrates W are loaded or unloaded may be formed on the housing 410. Further, a door (not shown) selectively opening and closing the opening may be installed on the housing 410.

The cup 420 may have a box shape with an open top. The cup 420 may have a processing space and substrates W can be liquid-processed in the treatment space. The supporting unit 440 supports substrates W in the processing space. The liquid spray unit 460 discharges a processing solution to a substrate W supported on the supporting unit 440. A plurality of kinds of processing solutions is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to process a substrate. The recovery baths 422, 424, and 426 are each provided in a ring shape surrounding the supporting unit 440. The processing liquids splashed by rotation of a substrate W when the liquid processing process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and are provided such that the upper ends thereof protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected with the center of the underside of a substrate W, and rotates the supporting plate 442 about the center axis thereof.

According to an embodiment, the liquid spray unit 460 may include a nozzle 462. The nozzle 462 can discharge processing liquid to a substrate W. The processing liquid may be a chemical, a rinse solution, or an organic solvent. The chemical may be a chemical that has the property of strong acid or strong base. Further, the liquid spray unit 460 may include a plurality of nozzles 462 and the nozzles 462 can discharge different kinds of processing liquid. For example, any one of the nozzles 462 may discharge a chemical, another one of the nozzles 462 may discharge a rinse solution, and another one of the nozzles 462 may discharge an organic solvent. The liquid spray unit 460 is supplied with processing liquid (chemical) from a chemical supply apparatus 600.

The present disclosure can be applied to a wet etching process or a cleaning process of removing the film on the substrate surface and various processing liquids can be used in the process. The processing liquid that can be used in the present disclosure may include at least any one or more substances selected from hydrofluoric acid (HF), sulfuric acid (H₃SO₄), hydrogen peroxide (H₂O₂), nitric acid (HNO₃), phosphoric acid (H₃PO₄), ozonized water, or SC-1 solution (a mixture of ammonium hydroxide (NH₄OH), hydrogen peroxide (H₂O₂), and water (H₂O)), and may include processing liquid of various other substances that can be used in a substrate processing process.

The elevation unit 480 moves the cup 420 in the up-down direction. The relative height between the cup 420 and a substrate W is changed by up-down movement of the cup 420. Accordingly, the recovery baths 422, 424, and 426 that recover processing liquids are changed, depending on the kinds of processing liquids that are supplied to substrates W, so it is possible to separately recover processing liquids. Unlike the above description, the cup 420 may be fixed and the elevation unit 480 may move the supporting unit 440 in the up-down direction.

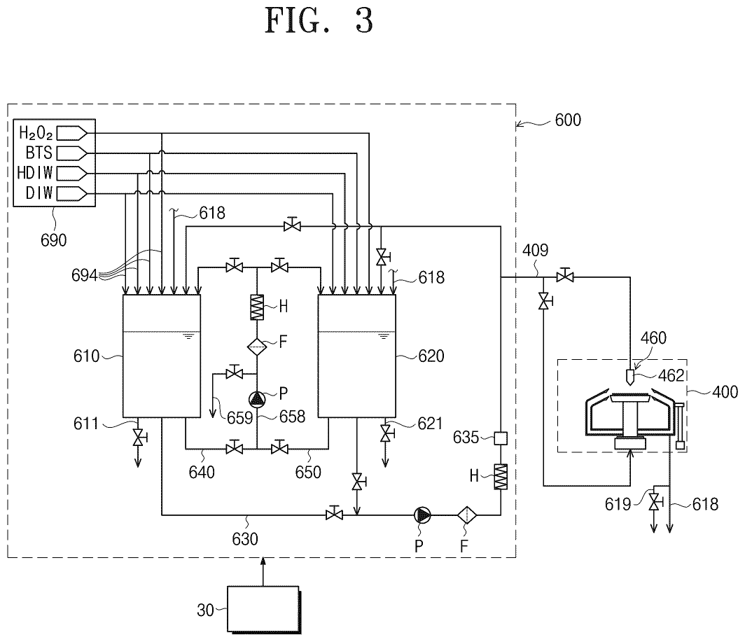

FIG. 3 is a view illustrating a chemical supply apparatus connected to a liquid processing chamber.

Referring to FIG. 3, the chemical supply apparatus 600 supplies a chemical that is used to process substrates to the liquid processing chamber 400.

The chemical supply apparatus 600 may be provided to supply a chemical to a plurality of liquid processing chambers 400. For example, a process of etching a TiN film on a substrate can be performed in the liquid processing chamber 400. When a chemical is continuously reused in the process of etching a TiN film, the concentration of TiN ions in the chemical increases. When a chemical with high concentration of Ti ions and a new chemical are mixed, the stability of the chemical may be deteriorated. Accordingly, a flushing process of removing the chemical remaining in the tanks and the circulation line of the chemical supply apparatus before supplying a new chemical is very important.

For example, the chemical supply apparatus 600 may include a first tank 610, a second tank 620, a chemical supply source 690, a main circulation line 630, a first sub-circulation line 640, a second sub-circulation line 650, and a control unit 30. The control unit 30 can control the first tank 610, the second tank 620, the chemical supply source 690, the main circulation line 630, the first sub-circulation line 640, and the second sub-circulation line 650. Though not shown, the chemical used in the liquid processing chamber 400 can be recovered to the first tank 610 or the second tank 620 through the recovery line 618 and can be reused.

Chemicals to be supplied to the liquid processing chamber 400 are stored in the first tank 610 and the second tank 620. The first tank 610 and the second tank 620 can be supplied with concentrates from the chemical supply source 690.

The first sub-circulation line 640 and the main circulation line 630 may be connected to the first tank 610. A pump P, a filter F, and a heater H may be installed on the main circulation line 630. A supply line 409 of the liquid processing chamber 400 is connected to the main circulation line 630. The supply line 409 may be connected to the nozzle 462 of the liquid spray unit 460 shown in FIG. 2. The first sub-circulation line 640 circulates the chemical stored in the first tank 610. A pump P, a filter F, and a heater H may be installed on the first sub-circulation line 640.

The liquid processing chamber 400 is connected to the first tank 610 through recovery line 618. The chemical used in the liquid processing chamber 400 can be recovered to the first tank 610 or the second tank 620 through the recovery line 618. Though not shown, a filter and a pump may be installed on the recovery line 618. A drain line 619 may be connected to the recovery line 618. The drain line 619 may be provided adjacent to the liquid processing chamber 400. A portion of the chemical used in the liquid processing chamber 400 can be drained through the drain line 619. The chemical that is drained may be limited to the initial amount of the chemical that is discharged from the liquid processing chamber 400. Since a high level of impurities are contained in the initial amount of chemical, when all the chemical is recovered to the first tank 610, it leads to an increase in the concentration of the chemical impurities in the first tank 610 (e.g., a increase in concentration of Ti ions). Accordingly, it is possible to reduce an increase of the concentration of impurities in the first tank 610 by draining the initial amount of chemical that is discharged from the liquid processing chamber 400. For example, assuming that a chemical is supplied to the liquid processing chamber 400 from the first tank 610 for 10 seconds, it is preferable to drain the chemical through the drain line 619 in the early stage of discharging the chemical from the liquid processing chamber 400 and then recover the chemical to the first tank 610 or the second tank 620 through the recovery line 618 thereafter.

A first drain line 611 is provided on the lower end of the first tank 610. The chemical reaching a lifetime can be drained through the first drain line 611 in liquid exchange for the first tank 610.

Meanwhile, source supply lines 694 for receiving concentrates from the chemical supply source 640 in liquid exchange may be connected to the first tank 610. For example, the chemical supply source 690 can supply high-temperature deionized water (HDIW), deionized water (DIW), Beol Tin Strip (BTS), hydrogen peroxide (H₂O₂), etc. to the first tank 610.

The second sub-circulation line 650 and the main circulation line 630 may be connected to the second tank 620. The second tank 620, in the same way as the first tank 610, can supply a chemical to the nozzle 462 of the liquid processing chamber 400 through the main circulation line 630.

The second sub-circulation line 650 circulates the chemical stored in the second tank 620. A pump P, a filter F, and a heater H may be installed on the second sub-circulation line 650. The pump P, filter F, and heater H installed on the second sub-circulation line 650 can be used to mix the chemical in the second tank 620. The first sub-circulation line 640 and the second sub-circulation line 650 include a common line 658 to enable the shared use of a pump P, a filter F, and a heater H. The pump P, filter F, and heater H are installed in the common line 658. A drain line 659 is connected to the common line 658.

Meanwhile, source supply lines 690 for receiving concentrates from the chemical supply source 694 may be connected to the second tank 620. For example, the chemical supply source 690 can supply high-temperature deionized water (HDIW), deionized water (DIW), Beol Tin Strip (BTS), hydrogen peroxide (H₂O₂), etc. to the second tank 620.

The valves installed in the lines of the chemical supply apparatus 600 can be controlled by the control unit 30.

The chemical supply source 690 can supply a flushing chemical for flushing the main circulation line 630 and the sub-circulation lines 640 and 650 that are connected to the first tank 610 and the second tank 620 in a flushing mode. The flushing chemical may be the same liquid as deionized water or the chemical that is used in processes. The chemical supply source 690 can supply chemicals to the first tank 610 and the second tank 620 when the flushing mode is finished.

The control unit 30 can control the tanks 610 and 620 and the chemical supply source 690 to perform the flushing mode that drains the chemical (existing chemical) accommodated in the first tank 610 and the second tank 620 and removes the remaining chemical in the first sub-circulation line 640 and the second sub-circulation line 650, and the chemical exchange mode that exchanges chemicals by supplying a new chemical to the first tank 610 and the second tank 620.

The flushing mode may include: a primary flushing mode that supplies deionized water (flushing liquid) to the first tank 610 and then collects the deionized water to the second tank 620 through the main circulation line 630, and then drains the deionized water through the drain line 659 connected to the second sub-circulation line 650; and a secondary flushing mode that supplies deionized water to the second tank 620 and then collects the deionized water to the first tank 610 through the main circulation line 630, and then drains the deionized water through the drain line 659 connected to the first sub-circulation line 650.

The flushing ode includes an operation of feeding deionized water into any one tank of the first tank 610 and the second tank 620, a substation operation of substituting the liquid in the main circulation line 630, the other one tank, and the first and second sub-circulation lines 640 and 650 with deionized water, and a drain operation through the drain line 659 connected to the sub-circulation lines. The flushing mode is finished when a preset deionized water usage is reached. The deionized water usage can be checked through a flow meter 635 installed in the main circulation line 630. In the flushing mode, the deionized water supplied to the main circulation line 530 is all drained.

In the primary flushing mode, the chemical supply source 690 can supply deionized water to the first tank 610 when the level of the deionized water in the first tank 610 decreases under a predetermined level; and, in the secondary flushing mode, the chemical supply source 690 can supply deionized water to the second tank 620 when the level of the deionized water in the second tank 620 decreases under a predetermined level.

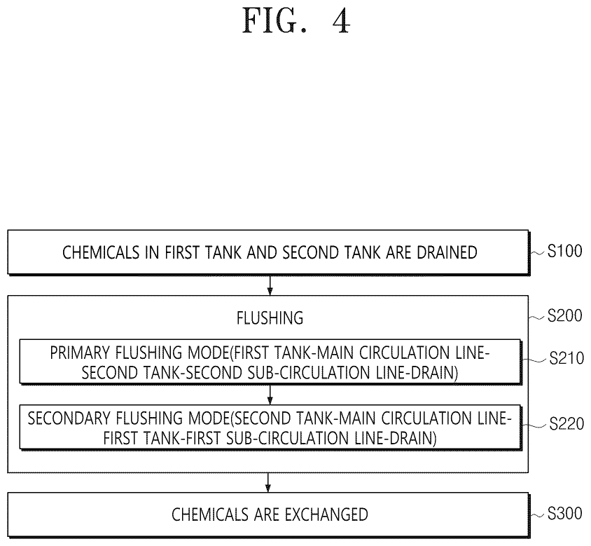

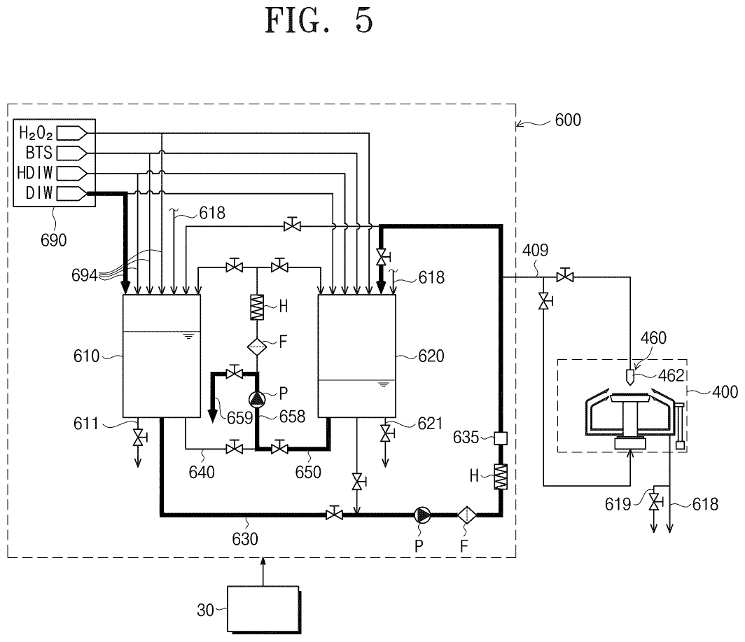

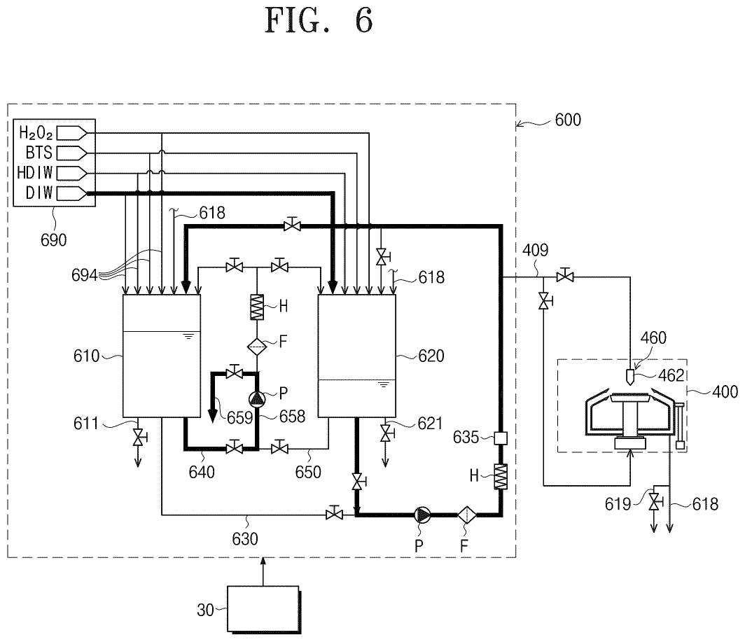

FIG. 4 is a flowchart illustrating a chemical supply method in the chemical supply apparatus, and FIG. 5 to FIG. 6 are views sequentially showing the chemical supply method.

Referring to FIG. 4 to FIG. 6, the chemical supply method may include a chemical drain step S100, a flushing step S200, and a chemical exchange step S300.

In the chemical drain step S100, the chemicals stored in the first tank 610 and the second tank 620 are all drained.

The flushing step S200 may include both of the primary flushing mode S210 and the second flushing mode S620. The flushing step S200, if necessary, may perform only any one of the primary flushing mode S210 or the second flushing mode S620.

In the primary flushing mode S210, deionized water (flushing liquid) is supplied to the first tank 610, the deionized water is collected to the second tank 620 through the main circulation line 630, and the deionized water is drained through the drain line 659 connected to the second sub-circulation line 650. The remaining chemical in the main circulation line 630 and the second sub-circulation line 650 can be substituted with deionized water through the primary flushing mode.

Since the substitution method described above uses the second tank 620, it can reduce the deionized water usage and decrease the neutralization time, as compared with a dilution method of supplying deionized water (flushing liquid) and then collecting the deionized water to the first tank 610 through the main circulation line 630 in the primary flushing mode S210.

In the secondary flushing mode S220, deionized water (flushing liquid) is supplied to the second tank 620, the deionized water is collected to the first tank 610 through the main circulation line 630, and the deionized water is drained through the drain line 659 connected to the first sub-circulation line 640. The remaining chemical in the main circulation line 630 and the first sub-circulation line 640 can be substituted with deionized water through the secondary flushing mode.

Since the substitution method described above uses the first tank 610, so it can reduce the deionized water usage and decrease the neutralization time, as compared with a dilution method of supplying deionized water (flushing liquid) and then collecting the deionized water to the second tank 620 through the main circulation line 630 in the secondary flushing mode S220.

The flushing mode is finished when the flow rate of deionized water passing through the main circulation line 630 reaches a target flow rate. When the flushing mode is finished, all the deionized water remaining in the first tank 610 and the second tank 620 is drained.

In the chemical exchange step S300, a new chemical can be supplied to the first tank 610 and the second tank 620. The new chemical can be supplied from the chemical supply source 690. When a new chemical is supplied to the first tank 610 and the second tank 620, internal circulation is performed through the sub-circulation lines 640 and 650.

As described above, according to the present disclosure, the remaining chemical in the circulation lines are substituted with deionized water and drained, whereby it is possible to quantify the deionized water usage regardless of the type, concentration, or mixing ratio of a chemical. Further, by quantifying the deionized water usage, the accuracy of the flushing mode (pipeline neutralization) can be ensured, and thus, the flushing mode can be reported in a computerized report format, whereby it is possible to expect a distinct effect being able to lower the environmental safety grade.

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

1-10. (canceled)

11. A chemical exchange method in a chemical processing apparatus including a first tank, a second tank, and a main circulation line connected to the first tank and the second tank, the chemical exchange method comprising:
a flushing step of draining a chemical accommodated in the first tank and the second tank, supplying a flushing liquid to the first tank, collecting the flushing liquid to the second tank through the main circulation line, and then draining the flushing liquid; and
a chemical exchange step of exchanging chemicals by supplying a new chemical to the first tank and the second tank.

12. The chemical exchange method of claim 11, wherein the flushing liquid collected to the second tank is drained through a drain line connected to a sub-circulation line circulating the chemical stored in the second tank.

13. The chemical exchange method of claim 12, wherein a flushing liquid is supplied to the first tank while the flushing step is performed.

14. The chemical exchange method of claim 13, wherein the flushing mode is finished when a flow rate of a flushing liquid that is provided to the second tank through the main circulation line reaches a target flow rate.

15. The chemical exchange method of claim 13, wherein the flushing step includes: a primary flushing mode that supplies a flushing liquid to the first tank, collects the flushing liquid to the second tank through the main circulation line, and then drains the flushing liquid; and a secondary flushing mode that supplies a flushing liquid to the second tank, collects the flushing liquid to the first tank through the main circulation line, and then drains the flushing liquid.

16. The chemical exchange method of claim 13, wherein the flushing liquid collected to the first tank in the secondary flushing mode is drained through a drain line connected to a sub-circulation line circulating the chemical stored in the first tank.

17. The chemical exchange method of claim 13, wherein the flushing liquid is deionized water.

18. A chemical exchange method in a chemical supply apparatus including a first tank, a second tank, and a main circulation line connected to the first tank and the second tank, the chemical exchange method comprising:
draining a chemical accommodated in the first tank and the second tank;
a flushing step of supplying a flushing liquid to the first tank, collecting the flushing liquid to the second tank through the main circulation line, and then draining the flushing liquid, and of supplying a flushing liquid to the second tank, collecting the flushing liquid to the first tank through the main circulation line, and then draining the flushing liquid; and
a chemical exchange step of exchanging chemicals by supplying a new chemical to the first tank and the second tank,
wherein the flushing step is finished when a flow rate of the flushing liquid passing through the main circulation line reaches a target flow rate.

19. The chemical exchange method of claim 18, wherein the flushing liquid collected to the second tank is drained through a drain line connected to a sub-circulation line circulating the chemical stored in the second tank.

20. The chemical exchange method of claim 19, wherein the flushing liquid collected to the first tank is drained through a drain line connected to a sub-circulation line circulating the chemical stored in the first tank.
